(19) United States
(12) Patent Application Publication
(10) Pub. No.: US 2026/0123364 A1
(43) Pub. Date: Apr. 30, 2026

(54) TEST SYSTEM FOR SEMICONDUCTOR PACKAGE STRUCTURES WITH STEPPED SOCKET HOUSING PLATE AND METHODS OF USING THE SAME

(71) Applicant: Taiwan Semiconductor Manufacturing Company Limited, Hsinchu (TW)

(72) Inventors: Edward JUAN, Taoyuan City (TW); Shu-Jung TSENG, Wuci Township (TW); Hui-Chang YU, Hsinchu (TW); F.C. LEE, Hsinchu City (TW); Jacky TZUU, Hsinchu City (TW)

(21) Appl. No.: 18/928,146

(22) Filed: Oct. 27, 2024

(51) Int. Cl. H01L 21/66; G01R 1/04; H01L 21/67

(52) U.S. Cl. CPC H10P 74/277; G01R 1/0466; H10P 72/0616; H10P 74/203

(57) ABSTRACT

Test systems and methods testing semiconductor package structures including an improved socket housing plate design that provides improved testing reliability and accuracy. The upper surface of the socket housing plate includes a non-planar shape, such as a stepped configuration including a plurality of different regions having different vertical elevations. The non-planar shape of the upper surface of the socket housing plate may mimic the warpage characteristics of the semiconductor package structures being tested, which may enable improved contact between the semiconductor package structure and the contact pins of the test system. This may improve the accuracy of the testing and reduce the occurrence of “false reject” tests.

### BACKGROUND

The semiconductor industry has continually grown due to continuous improvements in integration density of various electronic components, e.g., transistors, diodes, resistors, capacitors, etc. For the most part, these improvements in integration density have come from successive reductions in minimum feature size, which allows more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a top view of an in-progress multi-chip module (MCM) package according to various embodiments of the present disclosure.

FIG. 1B is a vertical cross-section view of the in-progress MCM package taken along line A-A′ in FIG. 1A.

FIG. 2A is a vertical cross-section view of a portion of a test system for testing semiconductor package structures according to various embodiments of the present disclosure.

FIG. 2B is a top view of the socket housing plate of the test system in FIG. 2A illustrating different regions of the upper surface of the socket housing plate according to various embodiments of the present disclosure. The vertical cross section in FIG. 2A is taken along line A-A′ in FIG. 2B.

FIG. 3A is a vertical cross-section view of an in-progress MCM package disposed in the test system of FIGS. 2A and 2B according to various embodiments of the present disclosure.

FIG. 3B is a vertical cross-section view of an in-progress MCM package undergoing a testing process by the test system of FIG. 3A according to various embodiments of the present disclosure.

FIG. 4 is a vertical cross-section view of a portion of a test system for testing semiconductor package structures according to another embodiment of the present disclosure.

FIG. 5 is a flow chart showing a method of testing a semiconductor package structure according to various embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

The present disclosure is directed to test systems used for testing of semiconductor package structures and methods therefor. In particular, various embodiment include test systems having an improved socket housing plate design that enables more reliable and accurate testing of semiconductor package structures.

A semiconductor package often includes multiple semiconductor integrated circuit (IC) devices, which may also be referred to as “chips” or “dies,” mounted to a single support, or “package substrate.” A semiconductor package that includes multiple dies on a package substrate may be referred to as a “multi-chip module” (MCM) package. The assembly process for fabricating an MCM package is typically a multi-step process that may include, for example, placing dies on a front side of a package substrate, performing a bonding process to mechanically and electrically couple the dies to the package substrate, performing an encapsulation process that may include providing a molding compound or other suitable protective material around and between the dies, and optionally providing other components, such as a lid, a heat spreader, etc., over the dies and the molding compound. In some cases, bonding features, such as a ball grid array (BGA) may be provided on the back side of the package substrate to enable the MCM package to be bonded to another structure, such as a printed circuit board (PCB).

In some cases, the assembly process for an MCM package may occur in multiple stages. For example, dies of a first type (e.g., logic dies, such as CPU die(s), GPU die(s), ASIC die(s), etc.) may be mounted to the package substrate and encapsulated using a suitable encapsulant material. Subsequently, one or more additional dies of a second type (e.g., one or more memory dies, such as SRAM die(s), HBM die(s), etc.), may be mounted to the package substrate. Other components, such as a lid, heat spreader and/or bonding features may then be provided.

In some embodiments, it may be advantageous to perform testing of the MCM package at various stages of the assembly process. A specialized test system (which may also be referred to as a “tester”) may be used to test and validate the designed functionality of the MCM package and the components thereof. The testing process may include placing partially-and/or fully-assembled MCM packages into a socket of the test system. The socket may include an open interior region or socket housing that includes a socket housing plate at the bottom of the socket housing. A plurality of contact pins may extend through openings in the socket housing plate into the socket housing. Each of the contact pins may be connected to a circuit board (which may also be referred to as a “load board”) on which the socket is supported. The test system may also include a contact blade that may be configured to apply a controlled pressure to the upper surface of the MCM package to secure engagement between electrical contacts (e.g., bonding pads, solder balls, etc.) located on the underside of the MCM package and respective contact pins within the socket housing. The test system may be configured to transmit electrical test signals to the MCM package through the load board and the contact pins and to detect electrical response signals from the MCM package that are received through the contact pins and the load board. The detected response signals from the MCM package may be analyzed and used to determine whether the MCM package includes any functional defects.

Performing an above-described test multiple times during the assembly of an MCM package may enable the identification of faulty or defective devices at a relatively early stage of the assembly process, which may result in enhanced cost savings. For example, an initial test may be performed after dies of a first type (e.g., logic dies) are mounted to the package substrate and encapsulated, and a second test may be performed after final assembly is completed.

However, related testers are often not well-suited for testing partially-assembled (i.e., “in-progress”) MCM packages. In particular, in-progress MCM packages are often subject to a high degree of warpage (e.g., >400 μm die warpage and >800 μm package warpage at room temperature) that may result in the in-progress MCM package having a curved (e.g., convex or concave) shape. This may lead to poor contact between the electrical contacts on the underside of the in-progress MCM package and the contact pins of the tester. In many cases, poor electrical contact between the in-progress MCM package and the contact pins of the tester may lead to some in-progress MCM packages being incorrectly identified as having minor or no defects resulting in the MCM package failing the test process. In other words, the tester may falsely indicate that valid in-progress MCM packages have functional defects. This may result in functional inventory being unnecessarily discarded or otherwise removed from the production process, which may increase material losses and raise overall manufacturing costs.

Accordingly, there is a need for improvements in test systems used to test the functionality of semiconductor package structures, such as in-progress MCM packages. Various embodiments of the present disclosure include test systems and methods testing semiconductor package structures. Test systems according to various embodiments may include an improved socket housing plate design that provides improved testing reliability and accuracy. In various embodiments, the upper surface of the socket housing plate may have a non-planar shape, such as a stepped configuration including a plurality of different regions having different vertical elevations. In various embodiments, the non-planar shape of the upper surface of the socket housing plate may be complementary to the non-planar shape of the lower surface of the semiconductor package structure that is tested by the test system. Accordingly, the upper surface of the socket housing plate may mimic the warpage characteristics of the semiconductor package structure, which may enable the improved contact between the electrical contacts on the lower surface of the semiconductor package structure and the contact pins of the test system. This may improve the accuracy of the testing and reduce the occurrence of “false reject”test results.

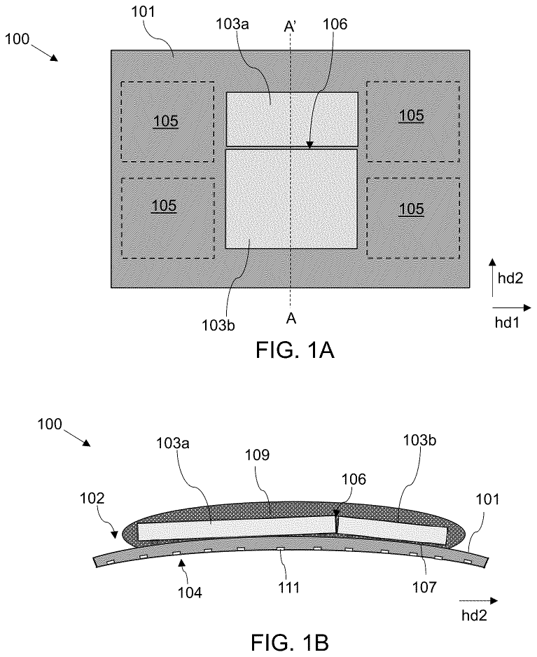

FIG. 1A is a top view of an in-progress multi-chip module (MCM) package 100 according to various embodiments of the present disclosure. FIG. 1B is a vertical cross-section view of the in-progress MCM package 100 taken along line A-A′ in FIG. 1A. Referring to FIGS. 1A and 1B, the in-progress MCM package 100 may include a substrate 101 having a first (i.e., upper) surface 102 and a second (i.e., bottom) surface 104. The package substrate 101 may include a suitable support element on which a plurality of semiconductor dies may be mounted. In various embodiments, the package substrate 101 may include a suitable dielectric material. In some embodiments, the dielectric material of the package substrate 101 may include an organic dielectric material. In one non-limiting embodiment, the package substrate 101 may include a solid substrate core composed of a sheet of laminate reinforced resin with layers of a polymer-based dielectric material, such as Ajinomoto Buildup Film (ABF)® product from Ajinomoto Co., Inc., Tokyo, JP, located over the surfaces of the substrate core. Conductive interconnect features (e.g., metal lines, vias and/or bonding pads) may extend through the dielectric material(s) of the package substrate 101 between the first side 102 and the second side 104 of the package substrate 101. The conductive interconnect features may include a plurality of bonding pads 111 located on the second side 104 of the package substrate 101. An optional outer coating layer (e.g., a solder resist layer) may be located on the first and second sides 102 and 104 of the package substrate 101. Other suitable materials and/or configurations for the package substrate 101 are within the contemplated scope of disclosure.

Referring again to FIGS. 1A and 1B, a plurality of dies 103a and 103b may be mounted over the first side 102 of the package substrate 101. Although FIGS. 1A and 1B illustrate a first die 103a and a second die 103b mounted to the package substrate 101, it will be understood that a greater or lesser number of dies may be mounted to the package substrate 101. Each of the dies 103a and 103b may include any suitable die, such as a logic die (e.g., a CPU die, a GPU die, an ASIC die, etc.), a memory die (e.g., an SRAM die, an HBM die, etc.), an analog die, an RF die, an integrated passive device (IPD) die, a deep trench capacitor (DTC) die, a non-functional “dummy” die, etc., including various combinations thereof. The dies 103a and 103b may be bonded to the package substrate 101 via a plurality of bonding features 107 that may provide a physical and electrical connection between the dies 103a and 103b and the package substrate 101. The bonding features 107 may electrically connect the dies 103a and 103b to conductive interconnect features extending within the underlying package substrate 101. In some embodiments, an underfill material (not shown in FIGS. 1A and 1B) may be provided between the dies 103a and 103b and the first surface 102 of the package substrate 101 and may laterally surround the bonding features 107.

The dies 103a and 103b may be bonded to the package substrate 101 using any suitable bonding technique, such as a microbump bonding technique, a direct bond (e.g., a metal-to-metal and dielectric-to-dielectric) bonding technique, a flip chip bonding technique, etc., including various combinations thereof. In some embodiments, the dies 103a and 103b may be directly attached to the first side 102 of the package substrate 101. Alternatively, or in addition, one or more dies 103a and 103b may be attached to an intervening structure, such as an interposer, that may be mounted to the first side 102 of the package substrate 101. The interposer may electrically couple the dies 103a and 103b to the package substrate 101. The dies 103a and 103b may be laterally spaced from one another such that there is a gap 106 located between adjacent dies 103a and 103b.

Referring to FIG. 1B, an encapsulant material 109 may surround the plurality of dies 103a and 103b mounted to the package substrate 101. For clarity of illustration, the encapsulant material 109 is omitted from the top view of the in-progress MCM package 100 shown in FIG. 1A. The encapsulant material 109 may contact lateral side surfaces and optionally the upper surfaces 103a and 103b of the dies 103a and 103b and may fill the gaps 106 between adjacent dies 103a and 103b. In some embodiments, the encapsulant material 109 may include an epoxy material. For example, the encapsulant material 109 may include an epoxy mold compound (EMC) that may include epoxy resin, a hardener (i.e., a curing agent), silica or other filler material(s), and optionally additional additives. The EMC may be applied around and optionally over the dies 103a and 103b in liquid or solid form, and may be hardened (i.e., cured) to form an encapsulant material 109 having sufficient stiffness and mechanical strength. Other suitable materials for the encapsulant material 109, such as a molded underfill (MUF) material, may also be utilized.

The in-progress MCM package 100 shown in FIGS. 1A and 1B may be in a state of partial assembly. In various embodiments, the dies 103a and 103b that are mounted to the package substrate 101 and encapsulated by the encapsulant material 109 may be a first set of dies 103a and 103b. The package substrate 101 may include one or more additional mounting regions 105 (indicated by dashed lines in FIG. 1A) to which a second set of one or more dies may be subsequently mounted. In some embodiments, the first set of dies 103a and 103b may be dies of a first type, such as logic dies, and the second set of dies may be dies of a second type, such as memory dies.

In many cases, the processing steps utilized to form an in-progress MCM package 100 as shown in FIGS. 1A and 1B may induce warpage of the package substrate 101. This is illustrated in FIG. 1B, which shows the package substrate 101 having a non-planar curved shape that “bows” downwards towards the periphery of the package substrate 101. In other embodiments, the warpage of the package substrate 101 may cause the package substrate 101 to “bow” upwards towards the periphery of the package substrate 101. As a result of this warpage, the lower surface of the in-progress MCM package 100 (which in the embodiment of FIG. 1B is defined by the second surface 104 of the package substrate 101) may not be flat and may instead have a curved or other non-planar shape. In contrast, a fully assembled MCM package 100 will often include a lid, a heat spreader and/or another component mounted to the package substrate 101 such that the lower surface of the MCM package 100 may have a generally flat planar surface. In the embodiment of FIG. 1B, the non-planar lower surface of the in-progress MCM package 100 includes a concave curved shape. In other embodiments, the lower surface of the in-progress MCM package 100 may have a convex curved shape. As discussed above, a curved shape of the in-progress MCM package 100 may make testing of the package difficult or unreliable using current testing systems. In particular, the warpage-induced curved shape of the in-progress MCM package 100 may result in poor electrical contact between the contact pins of the tester and the bonding pads 111 located on the second side 104 of the package substrate 101 of the in-progress MCM package 100. Accordingly, because of this poor contact the tester may erroneously indicate that an in-progress MCM package 100 is defective when the in-progress MCM package 100 is not in fact defective—i.e., the tester may produce a “false reject” result. In some cases, the percentage of such “false reject” test results from the tester (which may also be referred to as the “overkill” rate of the tester) may exceed 20% of the total number of in-progress MCM packages 100 that are tested. Such an overkill rate can result in an excessive quantity of functional, non-defective MCM packages 100 being unnecessarily discarded or otherwise removed from the production process, which may increase material losses and/or raise overall manufacturing costs.

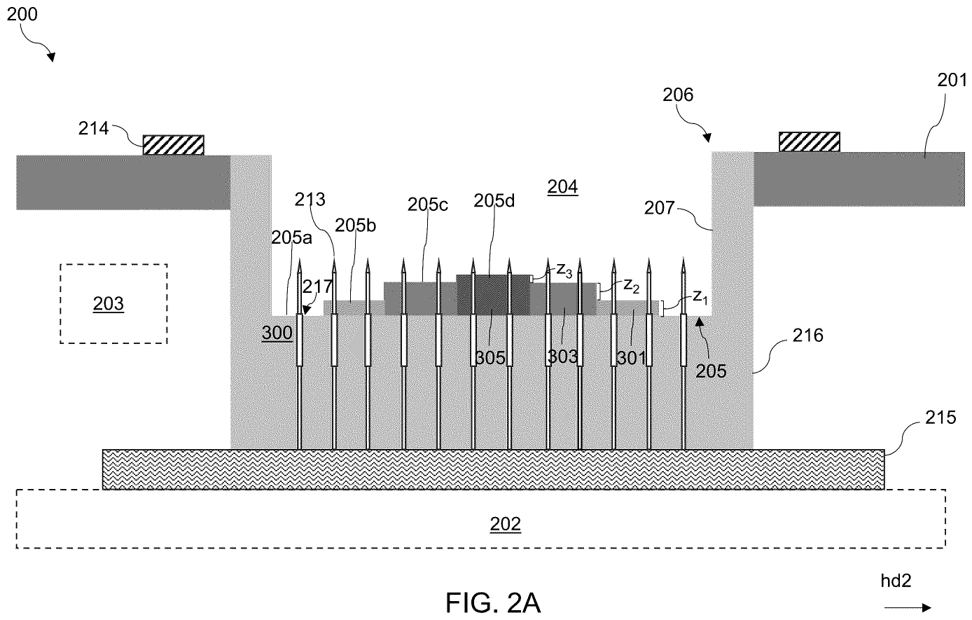

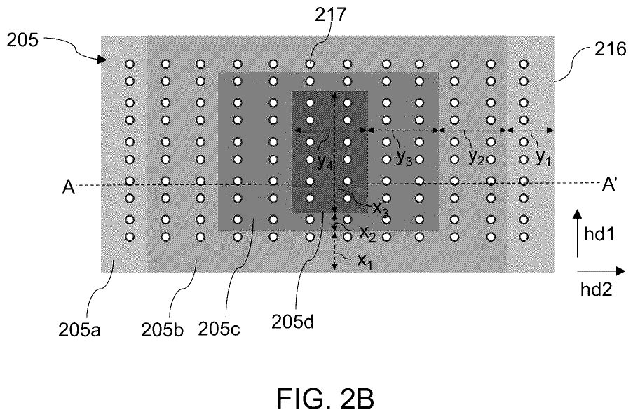

FIG. 2A is a vertical cross-section view of a portion of a test system 200 for testing semiconductor package structures according to various embodiments of the present disclosure. Referring to FIG. 2A, the test system 200 may include a controller 203 (e.g., a processor) that may control the operations of the test system 200 and a test head 202. In various embodiments, a socket 206 may be disposed on the test head 202. The socket 206 may be an electro-mechanical interface that may provide reliable electrical signal paths between the controller 203 of the test system 200 and a device under test, such as an above-described in-progress MCM package 100. The socket 206 may include an open interior region or socket housing 204 defined by a socket housing plate 216 and one or more socket housing sidewalls 207. The socket 206 may be attached to a socket base 201 such that the socket housing plate 216 may be recessed relative to the socket base 201.

The socket housing plate 216 may include a plurality of openings 217. A plurality of contact pins 213 may extend through the openings 217 in the socket housing plate 216 into the socket housing 204. The contact pins 213 may include an electrically conductive material. In some embodiments, the contact pins 213 may be spring-loaded contact pins (e.g., pogo pins). Each of the contact pins 213 may be electrically coupled to a circuit board 215, which may also be referred to as a “load board.” The load board 215 may be disposed on the test head 202 and the socket 206 may be located over the load board 215. The load board 215 may provide an electrical interface between the contact pins 213 and the controller 203 of the test system 200.

In various embodiments, the socket housing plate 216 may have a non-planar upper surface 205. In some embodiments, the non-planar upper surface 205 of the socket housing plate 216 may have a stepped configuration including different regions 205a, 205b, 205c and 205d each having a different vertical elevation. FIG. 2B is a top view of the socket housing plate 216 of FIG. 2A illustrating the different regions 205a, 205b, 205c and 205d of the upper surface 205 of the socket housing plate 216 according to various embodiments of the present disclosure. The vertical cross section in FIG. 2A is taken along line A-A′ in FIG. 2B.

FIG. 2B illustrates the openings 217 in the socket housing plate 216, but for clarity of illustration, the contact pins 213 within each opening 217 are omitted from FIG. 2B. Referring to FIGS. 2A and 2B, in one non-limiting embodiment, a first region 205a of the upper surface 205 of the socket housing plate 216 may extend along peripheral sides of the socket housing plate 216 and may have a first vertical elevation. A second region 205b of the upper surface 205 of the socket housing plate 216 may be located interior to the first region 205a and may have a second vertical elevation that is higher than the first vertical elevation. In the embodiment of FIGS. 2A and 2B, the first region 205a may include two strip-shaped portions extending along two opposite sides of the socket housing plate 216 (i.e., along the left-and right-hand sides of the socket hosing plate 216) and the second region 205b may extend interior of the strip-shaped portions of the first region 205a along the second horizontal direction hd2 and may extend to the edges of the socket hosing plate 216 along the first horizontal direction hd1. A third region 205c of the upper surface 205 of the socket housing plate 216 may be located radially inward from the second region 205b and may have a third vertical elevation that is higher than the second vertical elevation. In the embodiment of FIGS. 2A and 2B, the third region 205c is laterally surrounded by the second region 205b on all sides. A fourth region 205d of the upper surface 205 of the socket housing plate 216 is located in the center of the socket housing plate 216 and is laterally surrounded by the third region 205c on all sides. The fourth region 205d may have a fourth vertical elevation that is higher than the third vertical elevation. Other suitable configurations and/or shapes for the first, second, third, and fourth regions 205a-205d are within the contemplated scope of disclosure. In addition, it will be understood that although FIGS. 2A and 2B illustrate an embodiment in which the upper surface 205 of the socket housing plate 216 includes four regions 205a, 205b, 205c and 205d having different vertical elevations, it will be understood that the upper surface 205 of the socket housing plate 216 may have a greater or lesser number of regions having different vertical elevations. In each of the first through fourth regions 205a, 205b, 205c and 205d, the upper surface 205 of the socket housing plate 216 may be a planar surface extending parallel to first and second horizontal directions hd1 and hd2.

In various embodiments, the stepped configuration of the upper surface 205 of the socket housing plate 216 may correspond to the warpage characteristics of the in-progress MCM packages 100 that are tested by the test system 200. For example, in embodiments in which the in-progress MCM packages 100 have a non-planar curved shape that “bows” downwards towards the periphery of the package substrate 101 such as shown in FIG. 1B, the non-planar upper surface 205 of the socket housing plate 216 may have a generally convex shape that may be complementary to the concave shape of the lower surface of the in-progress MCM packages 100 (i.e., the second side 104 of the package substrate 101). Thus, in the embodiment of FIGS. 2A and 2B, the fourth region 205d of the upper surface 205 of the socket housing plate 216 located in the central region of the socket hosing plate 216 may have the highest vertical elevation. The vertical elevation of the upper surface 205 of the socket housing plate 216 may decrease in a stepwise manner from the center towards the periphery of the socket housing plate 216 from the fourth region 205d to the third region 205c and to the second region 205b along the first horizontal direction hd1, and from the fourth region 205d to the third region 205c, to the second region 205b, and to the first region 205a along the second horizontal direction hd2. In various embodiments, by providing a non-planar upper surface 205 of the socket housing plate 216 that is complementary to the shape of the lower surface of the in-progress MCM packages 100, contact between the contact pins 213 of the test system 200 and the bonding pads 111 on the underside 104 of the package substrate 101 of the in-progress MCM packages 100 may be improved, which can result in more accurate testing with reduced “overkill” rates. Accordingly, manufacturing costs for MCM packages 100 may be reduced.

Referring to FIG. 2A, in various embodiments, the step height Z₁ between the vertical elevation of the first region 205a and the vertical elevation of the second region 205b of the upper surface 205 of the socket housing plate 216 may be between about 50 μm and about 100 mm. The step height Z₂ between the vertical elevation of the second region 205b and the vertical elevation of the third region 205c of the upper surface 205 of the socket housing plate 216 may be between about 50 μm and about 100 mm. The step height Z₃ between the vertical elevation of the third region 205c and the vertical elevation of the fourth region 205d of the upper surface 205 of the socket housing plate 216 may be between about 50 μm and about 100 mm. However, greater or lesser step heights Z₁, Z₂, and Z₃ may also be utilized. The step heights Z₁, Z₂, and Z₃, may be uniform, or may vary between the different regions 205a, 205b, 205c, 205d of the upper surface 205 of the socket housing plate 216.

Referring to FIG. 2B, in various embodiments, the width dimension x₁ of the second region 205b between the periphery of the upper surface 205 of the socket housing plate 216 and the third region 205c along the first horizontal direction hd1 may be between about 100 μm and about 150 mm. The width dimension x₂ of the third region 205c between the second region 205b and the fourth region 205d along the first horizontal direction hd1 may be between about 100 μm and about 150 mm. The width dimension x₃ of the fourth region 205d along the first horizontal direction hd1 may be between about 100 μm and about 150 mm.

In various embodiments, the lateral dimension y₁ of the first region 205a between the periphery of the upper surface 205 of the socket housing plate 216 and the second region 205b along the second horizontal direction hd2 may be between about 100 μm and about 150 mm. The lateral dimension y₂ of the second region 205b between the first region 205a and the third region 205c along the second horizontal direction may be between about 100 μm and about 150 mm. The lateral dimension y₃ of the third region 205c between the second region 205b and the fourth region 205d along the second horizontal direction may be between about 100 μm and about 150 mm. The width dimension y₄ of the fourth region 205d along the second horizontal direction hd2 may be between about 100 μm and about 150 mm. However, greater or lesser width dimensions along the first horizontal direction hd1 and/or the second horizontal direction hd2 for each of the first region 205a, the second region 205b, the third region 205c and the fourth region 205d may also be utilized. The width dimensions or each region along the first horizontal direction hd1 may be uniform, or may vary between the different regions. The lateral dimensions or each region along the second horizontal direction hd2 may be uniform, or may vary between the different regions.

In some embodiments, the non-planar upper surface 205 of the socket housing plate 216 may be formed by providing a body 300 having a planar upper surface. The body 300 of the socket housing plate 216 may be formed of a suitable structural material, such as an engineering plastic (e.g., a polyamide-based material, a polyether ether ketone (PEEK)-based material, etc.). Other suitable materials for the body 300 of the socket housing plate 216, such as a metal material, are within the contemplated scope of disclosure. An array of openings 217 for the above-described contact pins 213 may be formed within the body 300 of the socket housing plate 216 using a suitable technique, such as a machining technique (e.g., milling, mechanical or laser drilling, etc.) or a molding technique. The stepped configuration of the upper surface 205 of the socket housing plate 216 may be provided by adding one or more inserts 301, 303, 305 over the planar upper surface of the body 300 of the socket housing plate 216. Each insert 301, 303, 305 may include an array of openings that correspond to the pattern of openings in the underlying planar surface of the body 300 of the socket housing plate 216 such that when the insert 301, 303, 305 is placed onto the body 300 of the socket housing plate 216, openings in the insert 301, 303, 305 are aligned with corresponding openings in the underlying body 300 of the socket housing plate 216. In some embodiments, the openings in the inserts 301, 303, 305 and the openings in the body 300 of the socket housing plate 216 may have a diameter that is at least about 0.45 mm, such as between about 0.45 mm and 90 mm. The inserts 301, 303, 305 may be utilized to vary the vertical elevation of different regions of the upper surface 205 of the socket housing plate 216. Thus, in the embodiment shown in FIGS. 2A and 2B, for example, the planar upper surface of the body 300 of the socket housing plate 216 may provide the first region 205a having the lowest vertical elevation, a first insert 301 may be provided over the body 300 to provide the second region 205b having a raised elevation relative to the first region 205a, a second insert 303 may be provided over the body 300 to provide the third region 205c having a raised elevation relative to the second region 205b, and a third insert 303 may be provided over the body 300 to provide the fourth region 205d having a raised elevation relative to the third region 205c. In some embodiments, the inserts 301, 303, 305 may be secured to the body 300 of the socket housing plate 216 using, for example, mechanical fasteners and/or a suitable adhesive. The inserts 301, 303 and 305 may be formed of a suitable structural material as described above. In some embodiments, the inserts 301, 303 and 305 may be formed of the same material(s) as the body 300 of the socket housing plate 216. Alternatively, one or more of the inserts 301, 303 and 305 may be formed of different material(s) than the body 300 of the socket housing plate 216.

In the embodiment shown in FIG. 2A, each of the inserts 301, 303 and 305 has a different thickness to provide a different vertical elevation of the upper surface 205 of the socket housing plate 216. In other embodiments, multiple inserts may be stacked on top of one another over the body 300 of the socket housing plate 216 to provide variations in the vertical elevation of different regions of the upper surface 205 of the socket housing plate 216. In still further embodiments, a single insert having a stepped upper surface may be placed of the body 300 to provide the variations in the vertical elevation of different regions of the upper surface 205 of the socket housing plate 216.

In various embodiments, utilizing one or more inserts 301, 303, 305 to modify the vertical elevation of different regions of the upper surface 205 of the socket housing plate 216 may enable the shape of the upper surface 205 to be modified to correspond to different warpage characteristics of the in-progress MCM packages 100. In some embodiments, different inserts 301, 303, 305 and/or different sets of inserts may be provided in different regions over the body 300 of the socket housing plate 216 to modify the topography of the upper surface 205 of the socket housing plate 216 based on the warpage characteristics of the in-progress MCM packages 100 being tested.

In other embodiments, the body 300 of the socket housing plate 216 may be formed having a stepped upper surface 200 using a suitable technique, such as via molding, machining and/or additive manufacturing processes.

In the embodiment shown in FIGS. 2A and 2B, each of the contact pins 213 of the test system 200 may have the same size and shape, including the same length dimension. The contact pins 213 may be placed in the openings 217 in the socket housing plate 216 such that the tip ends of the contact pins 213 may be substantially coplanar. The contact pins 213 may project above the upper surface 205 of the socket housing plate 216 by different distances in each region 205a, 205b, 205c and 205d of the upper surface 205 of the socket housing plate 216 due to the varying vertical height of the upper surface 205 of the socket housing plate 216 within each region 205a, 205b, 205c and 205d. In other embodiments, the contact pins 213 may have non-uniform shapes and/or sizes, such as non-uniform length dimensions, such that the tip ends 213 of the contact pins 213 may not all be in the same plane.

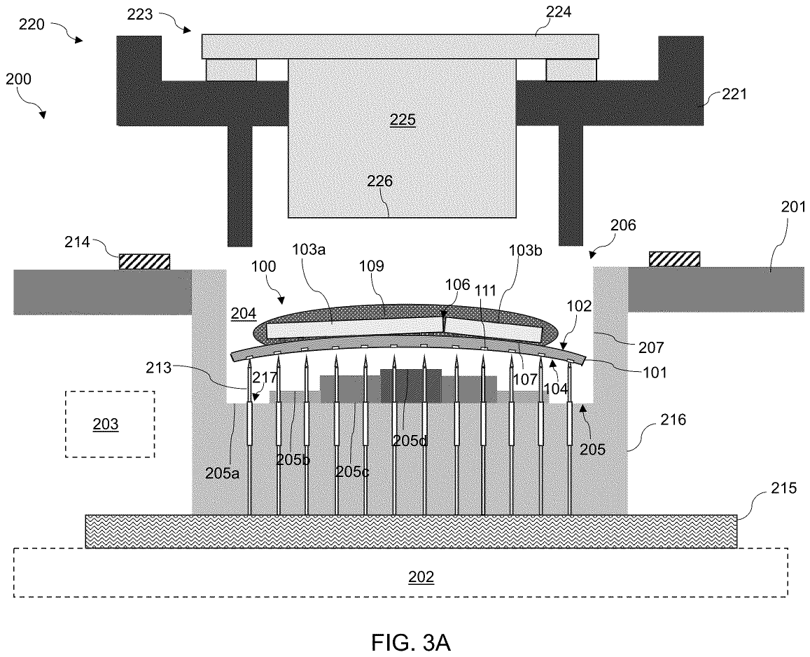

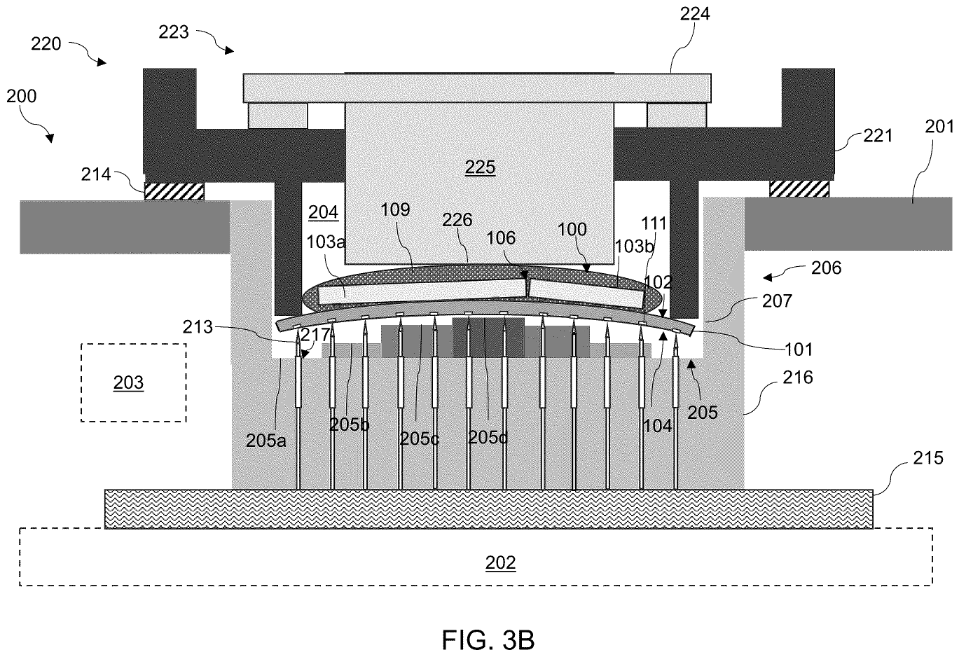

FIG. 3A is a vertical cross-section view of an in-progress MCM package 100 disposed in the test system 200 of FIGS. 2A and 2B according to various embodiments of the present disclosure. Referring to FIG. 3A, a material handling system (not shown in FIG. 3A) may be utilized to place an above-described in-progress MCM package 100 into the socket housing 204 of the test system 200. The in-progress MCM package 100 may be placed into the socket housing 204 such that each bonding pad 111 on the second side 204 of the in-progress MCM package 100 may be aligned with a corresponding contact pin 213 of the socket 106.

The test system 200 may further include a contact blade 220. The contact blade 220 may include a chuck 221 and a die pusher 223. The die pusher 223 may include an upper portion 224 and a lower portion 225 that extends through an opening in the chuck 221. The lower portion 225 of the die pusher 223 may have a lower surface 226 that is configured to engage with an upper surface of the in-progress MCM package 100 located within the socket housing 204. In some embodiments, the contact blade 220 may be positioned over the socket 106 such that the die pusher 223 may be aligned over the dies 103a and 103b of the in-progress MCM package 100.

FIG. 3B is a vertical cross-section view of an in-progress MCM package 100 undergoing a testing process by the test system 200 of FIG. 3A according to various embodiments of the present disclosure. Referring to FIG. 3B, the controller 203 of the test system 200 may cause the contact blade 220 to move vertically downwards towards the socket 206 such that the lower surface 226 of the lower portion 225 of the die pusher 223 contacts the upper surface of the in-progress MCM package 100 located in the socket housing 204. The contact blade 220 may apply a controlled downward pressure on the in-progress MCM package 100 that may cause the contact pins 213 of the socket 206 to engage with corresponding bonding pads 111 on the second surface 204 of the package substrate 101. In some embodiments, a lower portion of the chuck 221 may contact the upper surface 102 of the package substrate 101. In some embodiments, one or more mechanical stops 214, which may be located on the socket base 201, may prevent the contact blade 220 from exerting excessive pressure on the in-progress MCM package 100.

To perform a test on the in-progress MCM package 100, the controller 203 of the test system 200 may cause electrical test signals to be transmitted to the bonding pads 111 of the in-progress MCM package 100 via the load board 215 and the contact pins 213. Electrical response signals from the in-progress MCM package 100 may be received through the bonding pads 111, the contact pins 213 and the load board 215. The controller 203 may analyze the detected response signals from the in-progress MCM package 100 to determine whether the in-progress MCM package 100 includes any functional defects. Based on the testing, multiple in-progress MCM packages 100 may be sorted such that in-progress MCM packages 100 that are determined to not be defective may proceed to undergo additional package assembly processes while defective packages 100 may be segregated and optionally discarded. As discussed above, the non-planar upper surface 205 of the socket housing plate 216 may have a shape that is complementary to the shape of the lower surface of the in-progress MCM packages 100. This may help to improve the contact between the contact pins 213 of the test system 200 and the bonding pads 111 on the underside 104 of the package substrate 101 of the in-progress MCM packages 100 during the testing process. Thus, more accurate testing of the in-progress MCM packages 100 may be achieved, which can reduce the rate for “false negative” test results, and thereby improve manufacturing efficiency.

Following the testing process, the contact blade 220 may be moved vertically away from the in-progress MCM package 100 and the in-progress MCM package 100 may be removed from the socket housing 204 by the material handling system.

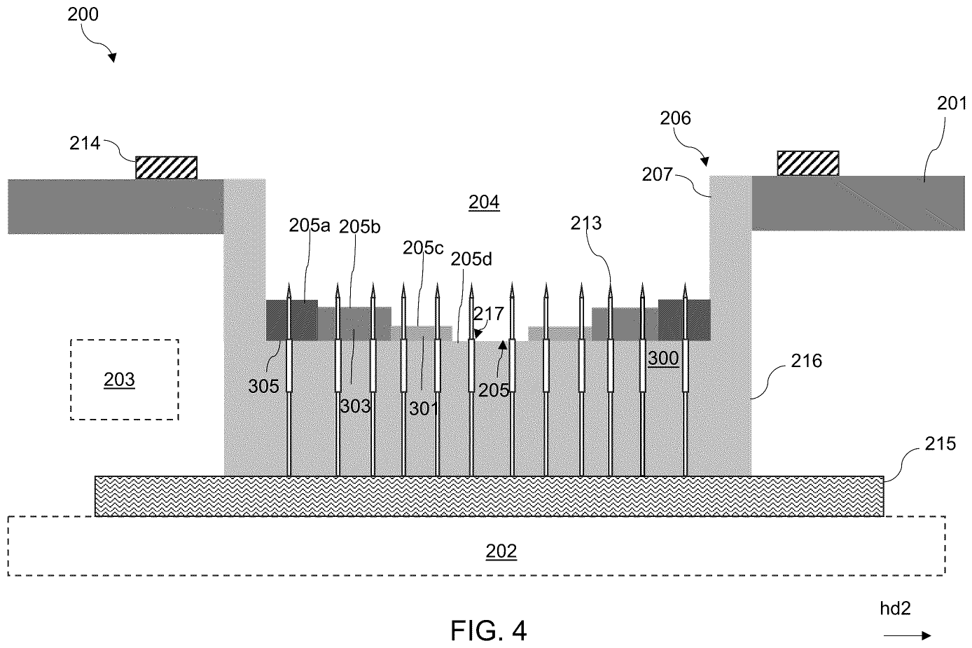

FIG. 4 is a vertical cross-section view of a portion of a test system 200 for testing semiconductor package structures according to another embodiment of the present disclosure. The test system 200 shown in FIG. 4 may be similar to the test system 200 described above with reference to FIGS. 2A and 2B. Thus, repeated discussion of like features is omitted for brevity. The test system 200 of FIG. 4 includes a socket 206 including a socket housing 204 and a socket housing plate 216 that forms a lower surface of the socket housing 204. The socket housing plate 216 has a non-planar upper surface 205 with a stepped configuration including different regions 205a, 205b, 205c and 205d each having a different vertical elevation. The embodiment of FIG. 4 differs from the embodiment of FIGS. 2A and 2B in that the central fourth region 205d may have the lowest vertical elevation located in a central region of the socket housing plate 216 and the elevation of the upper surface 205 increases in a stepwise manner from the center towards the periphery of the socket housing plate 216. In particular, the third region 205c may be laterally surround the second region 205b along at least the second horizontal direction hd2 and optionally also the first horizontal direction hd1, the second region 205b may laterally surround the third region 205c along at least the second horizontal direction hd2 and optionally also the first horizontal direction hd1. The first region 205a may laterally surround the second region 205b along at least the second horizontal direction hd2 and optionally also the first horizontal direction hd1. In some embodiments, the first region 205a may include two strip-shaped portions extending along two opposite sides of the socket housing plate 216 similar to the first region 205a shown in the embodiment of FIGS. 2A and 2B.

Referring again to FIG. 4, the stepped configuration of the upper surface 205 of the socket housing plate 216 may correspond to the warpage characteristics of the in-progress MCM packages 100 that are tested by the test system 200. For example, in embodiments in which the in-progress MCM packages 100 have a non-planar curved shape that “bows” upwards towards the periphery of the package substrate 101, such that the lower surface of the in-progress MCM package 100 (i.e., the second side 104 of the package substrate 101) may have a convex curved shape, the non-planar upper surface 205 of the socket housing plate 216 may have a generally concave shape that may be complementary to the convex shape of the lower surface of the in-progress MCM packages 100. Thus, in the embodiment of FIG. 4, the fourth region 205d of the upper surface 205 of the socket housing plate 216 located in the central region of the socket hosing plate 216 may have the lowest vertical elevation. The vertical elevation of the upper surface 205 of the socket housing plate 216 may increase in a stepwise manner from the center towards the periphery of the socket housing plate 216 from the fourth region 205d to the third region 205c, to the second region 205b, and optionally to the first region 205a along the first horizontal direction hd1, and from the fourth region 205d to the third region 205c, to the second region 205b, and to the first region 205a along the second horizontal direction hd2. In various embodiments, by providing a non-planar upper surface 205 of the socket housing plate 216 that is complementary to the shape of the lower surface of the in-progress MCM packages 100, contact between the contact pins 213 of the test system 200 and the bonding pads 111 on the underside 104 of the package substrate 101 of the in-progress MCM packages 100 may be improved, which can result in more accurate testing with reduced “overkill” rates. Accordingly, manufacturing costs for MCM packages 100 may be reduced.

In various embodiments, the step heights Z₁, Z₂, and Z₃ between the different regions 205a, 205b, 205c, and 205d, the width dimensions x₁, x₂, x₃, and the lateral dimensions y₁, y₂, y₃, and y₄ of the regions in the embodiment of FIG. 4 may be equivalent to those described above with reference to FIGS. 2A and 2B. In some embodiments, a socket housing plate 216 having a non-planar upper surface 205 as shown in FIGS. 2A and 2B may be modified to provide a socket housing plate 216 having a non-planar upper surface 205 as shown in FIG. 4, and vice versa, by rearranging and/or swapping out one or more inserts 301, 303 and 305 over the body 300 of the socket housing plate 216 as described above.

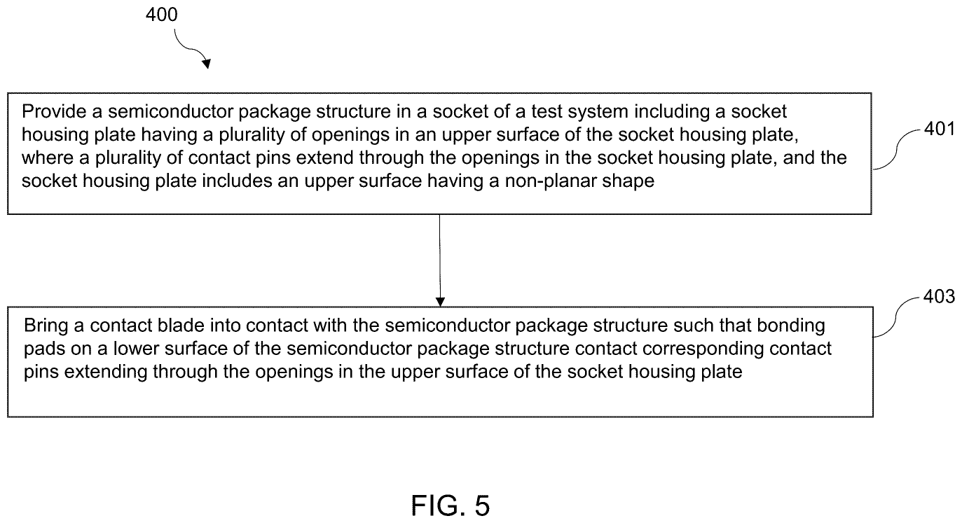

FIG. 5 is a flow chart showing a method 400 of testing a semiconductor package structure 100 according to various embodiments of the present disclosure. Referring to FIGS. 1A-3A, 4 and 5, in step 401 of method 400, a semiconductor package structure 100 may be provided in a socket 206 of a test system 200 including a socket housing plate 216 having a plurality of openings 217 in an upper surface 205 of the socket housing plate 216, where a plurality of contact pins 213 extend through the openings 217 in the socket housing plate 216, and the upper surface 205 of the socket housing plate 216 has a non-planar shape. Referring to FIGS. 3B and 5, in step 403 of method 400, a contact blade 220 may be brought into contact with an upper surface of the semiconductor package structure 100 such that bonding pads 111 on a lower surface 104 of the semiconductor package structure 100 contact corresponding contact pins 213 extending through the openings 217 in the upper surface 205 of the socket housing plate 216.

Referring to all drawings and according to various embodiments of the present disclosure, a test system 200 for testing semiconductor package structures 100 includes a socket 206 including a socket housing plate 216 including a plurality of openings 217 in an upper surface 205 of the socket housing plate 205, where the upper surface 205 of the socket housing plate 216 has a non-planar shape, and a plurality of contact pins 213 extending through the openings 217 into a housing 204 of the socket 206, and a contact blade 220 configured to contact an upper surface of a semiconductor package structure 100 located in the socket 206.

In an embodiment, the upper surface 205 of the socket housing plate 216 has a stepped configuration including a plurality of different regions 205a, 205b, 205c and 205d having different vertical elevations.

In another embodiment, the vertical elevation of the upper surface 205 of the socket housing plate 216 decreases in a stepwise manner from a central portion of the socket housing plate 216 towards a periphery of the socket housing plate 216.

In another embodiment, the upper surface 205 of the socket housing plate 216 includes a first region 205a including a pair of strip-shaped portions extending along two opposite sides of the socket housing plate 216, the first region having a first vertical elevation, a second region 205b located interior of the strip-shaped portions of the first region 205a, the second region 205b having a second vertical elevation that is greater than the first vertical elevation, a third region 205c located interior of the second region 205b and laterally surrounded by the second region 205b, the third region 205c having a third vertical elevation that is greater than the second vertical elevation, and a fourth region 205d located interior of the third region 205c and laterally surrounded by the third region 205c, the fourth region 205d having a fourth vertical elevation that is greater than the third vertical elevation.

In another embodiment, the vertical elevation of the upper surface 205 of the socket housing plate 216 increases in a stepwise manner from a central portion of the socket housing plate 216 towards a periphery of the socket housing plate 216.

In another embodiment, the upper surface 205 of the socket housing plate 216 includes a first region 205a including a pair of strip-shaped portions extending along two opposite sides of the socket housing plate 216, the first region having a first vertical elevation, a second region 205b located interior of the strip-shaped portions of the first region 205a, the second region 205b having a second vertical elevation that is less than the first vertical elevation, a third region 205c located interior of the second region 205b and laterally surrounded by the second region 205b, the third region 205c having a third vertical elevation that is less than the second vertical elevation, and a fourth region 205d located interior of the third region 205c and laterally surrounded by the third region 205c, the fourth region 205d having a fourth vertical elevation that is less than the third vertical elevation.

In another embodiment, a step height Z₁, Z₂, and Z₃ between each adjacent pair of regions 205a, 205b, 205c, 205d of the upper surface 205 of the socket housing plate 216 is between 50 μm and 100 mm.

In another embodiment, a width dimension x₁, x₂, x₃, and a lateral dimension y₁, y₂, y₃, and y₄ of each of the regions 205a, 205b, 205c, 205d of the upper surface of the socket housing plate along at least one horizontal direction (hd1, hd2) is between 100 μm and 150 mm.

In another embodiment, the socket housing plate 216 includes a body 300 having a planar upper surface and at least one insert 301, 303 and 305 over the body 305 to provide the upper surface 205 of the socket housing plate 216 including a plurality of different regions 205a, 205b, 205c, 205d having different vertical elevations.

In another embodiment, the non-planar shape of the upper surface 205 of the socket housing plate 216 corresponds to a warpage characteristic of the semiconductor package structure 100 located within the socket 206.

In another embodiment, the test system 200 further includes a circuit board 215, the socket 206 disposed on the circuit board 215, where the contact pins 213 include pogo pins and are electrically coupled to the circuit board 215.

Another embodiment is drawn to a socket 206 for a test system 200 for testing semiconductor package structures 200, including a socket base 201, a socket housing plate 216 recessed with respect to the socket base 201, the socket housing plate 216 including a plurality of openings 217 in an upper surface 205 of the socket housing plate 216, where the upper surface 205 of the socket housing plate 216 has a non-planar shape, and at least one sidewall 207 extending between the socket housing plate 216 and the socket base 201 such that a socket housing 204 is defined by the socket housing plate 216 and the at least one sidewall 217.

In an embodiment, the socket 206 further includes a plurality of contact pins 213 located in the openings 217 in the upper surface 205 of the socket housing plate 216, where tip ends of each of the contact pins 213 are located within the socket housing 204 and each of the contact pins 213 is electrically coupled to a circuit board 215 underlying the socket 206.

In another embodiment, the tip ends of each of the contact pins 213 are substantially coplanar, and the contact pins 213 project above the upper surface 205 of the socket housing plate 216 by different distances in different regions 205a, 205b, 205c, 205d of the socket housing plate 216.

In another embodiment, the socket housing plate 216 includes a base 300 having a planar upper surface and at least one insert 301, 303, 305 over the base 300 to provide a stepwise-configuration for the upper surface 205 of the socket housing plate 216.

Another embodiment is drawn to a method of testing a semiconductor package structure 100 that includes providing the semiconductor package structure 100 in a socket 206 of a test system 200 including a socket housing plate 216 having a plurality of openings 217 in an upper surface 205 of the socket housing plate 216, where a plurality of contact pins 213 extend through the openings 217 in the socket housing plate 216, and the socket housing plate 216 includes an upper surface 205 having a non-planar shape, and bringing a contact blade 220 into contact with the semiconductor package structure 100 such that bonding pads 111 on a lower surface 104 of the semiconductor package structure 100 contact corresponding contact pins 213 extending through the openings 217 in the upper surface 205 of the socket housing plate 216.

In an embodiment, the semiconductor package structure 100 includes an in-progress multi-chip module (MCM) package 100 having a plurality of semiconductor dies 103a, 103b mounted over an upper surface 102 of a package substrate 101, where the plurality of bonding pads 111 are located on a lower surface 104 of the package substrate 101, and where the non-planar shape of the upper surface 205 of the socket housing plate 216 corresponds to a warpage characteristic of the in-progress MCM package 100.

In one embodiment, the lower surface of the in-progress MCM package 100 has a concave shape, and a vertical elevation of the upper surface 205 of the socket housing plate 216 decreases in a stepwise manner from a central portion of the socket housing plate 216 towards a periphery of the socket housing plate 216.

In another embodiment, the lower surface 104 of the in-progress MCM package 100 has a convex shape, and a vertical elevation of the upper surface 205 of the socket housing plate 216 increases in a stepwise manner from a central portion of the socket housing plate 216 towards a periphery of the socket housing plate 216.

In another embodiment, the method further includes modifying a topography of the upper surface 205 of the socket housing plate 216 to correspond with the warpage characteristics of the in-progress MCM packages 100 being tested by rearranging and/or swapping out one or more inserts 301, 303, 305 over a body 300 of the socket housing plate 216.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A test system for testing semiconductor package structures, comprising:
a socket, comprising:
a socket housing plate comprising a plurality of openings in an upper surface of the socket housing plate, wherein the upper surface of the socket housing plate has a non-planar shape; and
a plurality of contact pins extending through the openings into a housing of the socket; and
a contact blade configured to contact an upper surface of a semiconductor package structure located in the socket.

2. The test system of claim 1, wherein the upper surface of the socket housing plate has a stepped configuration comprising a plurality of different regions having different vertical elevations.

3. The test system of claim 2, wherein a vertical elevation of the upper surface of the socket housing plate decreases in a stepwise manner from a central portion of the socket housing plate towards a periphery of the socket housing plate.

4. The test system of claim 3, wherein the upper surface of the socket housing plate comprises:
a first region comprising a pair of strip-shaped portions extending along two opposite sides of the socket housing plate, the first region having a first vertical elevation;
a second region located interior of the strip-shaped portions of the first region, the second region having a second vertical elevation that is greater than the first vertical elevation;
a third region located interior of the second region and laterally surrounded by the second region, the third region having a third vertical elevation that is greater than the second vertical elevation; and
a fourth region located interior of the third region and laterally surrounded by the third region, the fourth region having a fourth vertical elevation that is greater than the third vertical elevation.

5. The test system of claim 2, wherein a vertical elevation of the upper surface of the socket housing plate increases in a stepwise manner from a central portion of the socket housing plate towards a periphery of the socket housing plate.

6. The test system of claim 5, wherein the upper surface of the socket housing plate comprises:
a first region comprising a pair of strip-shaped portions extending along two opposite sides of the socket housing plate, the first region having a first vertical elevation;
a second region located interior of the strip-shaped portions of the first region, the second region having a second vertical elevation that is less than the first vertical elevation;
a third region located interior of the second region and laterally surrounded by the second region, the third region having a third vertical elevation that is less than the second vertical elevation; and
a fourth region located interior of the third region and laterally surrounded by the third region, the fourth region having a fourth vertical elevation that is less than the third vertical elevation.

7. The test system of claim 2, wherein a step height between each adjacent pair of regions of the upper surface of the socket housing plate is between 50 μm and 100 mm.

8. The test system of claim 2, wherein a width dimension and a lateral dimension of each of the first region, second region, third region, and fourth region of the upper surface of the socket housing plate along at least one horizontal direction is between 100 μm and 150 mm.

9. The test system of claim 2, wherein the socket housing plate comprises a body having a planar upper surface and at least one insert over the body to provide the upper surface of the socket housing plate comprising a plurality of different regions having different vertical elevations.

10. The test system of claim 1, wherein the non-planar shape of the upper surface of the socket housing plate corresponds to a warpage characteristic of the semiconductor package structure located within the socket.

11. The test system of claim 1, further comprising:
a circuit board, the socket disposed on the circuit board, wherein the plurality of contact pins comprise pogo pins and are electrically coupled to the circuit board.

12. A socket for a test system for testing semiconductor package structures, comprising:
a socket base;
a socket housing plate recessed with respect to the socket base, the socket housing plate comprising a plurality of openings in an upper surface of the socket housing plate, wherein the upper surface of the socket housing plate has a non-planar shape; and
at least one sidewall extending between the socket housing plate and the socket base such that a socket housing is defined by the socket housing plate and the at least one sidewall.

13. The socket of claim 12, further comprising:
a plurality of contact pins located in the openings in the upper surface of the socket housing plate, wherein tip ends of each of the plurality of contact pins are located within the socket housing and each of the plurality of contact pins is electrically coupled to a circuit board underlying the socket.

14. The socket of claim 13, wherein the tip ends of each of the plurality of contact pins are substantially coplanar, and the plurality of contact pins project above the upper surface of the socket housing plate by different distances in different regions of the socket housing plate.

15. The socket of claim 13, wherein the socket housing plate comprises a base having a planar upper surface and at least one insert over the base to provide a stepwise-configuration for the upper surface of the socket housing plate.

16. A method of testing a semiconductor package structure, comprising:
providing the semiconductor package structure in a socket of a test system comprising a socket housing plate comprising a plurality of openings in an upper surface of the socket housing plate, wherein a plurality of contact pins extend through the openings in the socket housing plate, and the socket housing plate comprises an upper surface having a non-planar shape; and
bringing a contact blade into contact with the semiconductor package structure such that bonding pads on a lower surface of the semiconductor package structure contact corresponding contact pins extending through the openings in the upper surface of the socket housing plate.

17. The method of claim 16, wherein the semiconductor package structure comprises an in-progress multi-chip module (MCM) package comprising a plurality of semiconductor dies mounted over an upper surface of a package substrate, wherein a plurality of bonding pads are located on a lower surface of the package substrate, and wherein the non-planar shape of the upper surface of the socket housing plate corresponds to a warpage characteristic of the in-progress MCM package.

18. The method of claim 17, wherein the lower surface of the in-progress MCM package has a concave shape, and a vertical elevation of the upper surface of the socket housing plate decreases in a stepwise manner from a central portion of the socket housing plate towards a periphery of the socket housing plate.

19. The method of claim 17, wherein the lower surface of the in-progress MCM package has a convex shape, and a vertical elevation of the upper surface of the socket housing plate increases in a stepwise manner from a central portion of the socket housing plate towards a periphery of the socket housing plate.

20. The method of claim 17, further comprising:
modifying a topography of the upper surface of the socket housing plate to correspond with the warpage characteristics of the in-progress MCM packages being tested by rearranging and/or swapping out one or more inserts over a body of the socket housing plate.
